(19) United States
(12) Patent Application Publication
(10) Pub. No.: US 2026/0254607 A1
(43) Pub. Date: Aug. 27, 2026

(54) INTEGRATED KALMAN FILTER-BASED PHASE-LOCKED LOOP AND VITERBI EQUALIZER

(71) Applicant: Silicon Laboratories Inc., Austin, TX (US)

(72) Inventors: Xushuai Qu, Austin, TX (US); Guner Arslan, Austin, TX (US)

(21) Appl. No.: 19/062,587

(22) Filed: Feb. 25, 2025

(51) Int. Cl. H04L 7/033; H03M 13/41; H04W 28/04

(52) U.S. Cl. CPC H04L 7/0334; H03M 13/4138; H04W 28/04

(57) ABSTRACT

A technique for reducing inter-symbol interference, frequency offset, and phase offset in a demodulator of a wireless communications system includes integrating a Kalman filter-based phase-locked loop (PLL) and a Viterbi equalizer. The integrated Kalman filter-based PLL and Viterbi equalizer includes a Kalman filter-based PLL that provides a frequency or phase offset corrected signal to a modified Viterbi equalizer and receives a reference signal for use in determining phase error. In an embodiment, the reference signal is based on an instant decision of the modified Viterbi equalizer rather than waiting for an entire traceback length of time to receive a Maximum Likelihood Sequence Estimation (MLSE) equalized symbol for use as the reference symbol by the Kalman filter-based PLL.

### BACKGROUND

### Field of the Invention

This disclosure relates to communications systems in general, and more particularly to receivers of wireless communications systems.

### Description of the Related Art

In an exemplary wireless communications system, a coherent demodulator (i.e., synchronous demodulator) extracts original data from a modulated signal by comparing the modulated signal to a reference signal or carrier with the same frequency and phase. In an exemplary Bluetooth® Low Energy (BLE) High Data Throughput (HDT) application, a receiver enables coherent demodulation by tracking phase and frequency and performing channel equalization to address inter-symbol interference (ISI) of a multi-path fading channel. Channel equalization is a technique that reduces or eliminates distortion (e.g., amplitude, frequency, or phase distortion) incurred by a signal as it travels through a transmission medium (e.g., air).

An exemplary receiver includes a phase-tracking loop (i.e. Kalman filter-based phase-locked loop (PLL)), which reduces or eliminates phase offset and frequency offset, and an equalizer that reduces or eliminates ISI. In general, a Maximum Likelihood Sequence Estimation (MLSE) equalizer, which is typically implemented using the Viterbi algorithm and is referred to as a Viterbi equalizer, has superior equalization performance as compared to conventional (e.g., Minimum Mean Squared Error (MMSE)) equalizers. Since performance of a Kalman filter-based PLL degrades if symbols received by the Kalman filter-based PLL include ISI, the Kalman filter-based PLL should receive equalized symbols. However, since performance of a Viterbi equalizer degrades if symbols received by the Viterbi equalizer include frequency or phase offset, the Viterbi equalizer should receive frequency or phase offset-corrected symbols. Therefore, the receiver path experiences some loss of performance regardless of whether equalization is performed before frequency or phase offset compensation or after the frequency or phase offset compensation. Accordingly, improved techniques for tracking frequency offset and equalizing a received signal are desired.

### SUMMARY OF EMBODIMENTS OF THE INVENTION

In an embodiment, a method for receiving a radio frequency signal includes correcting a frequency or phase offset in a baseband version of a received radio frequency signal to generate a corrected signal based on the baseband version of the received radio frequency signal and a feedback signal. The method includes equalizing the corrected signal using maximum likelihood signal estimation and a channel estimate to generate an equalized signal. The method includes providing the feedback signal. The feedback signal is based on the corrected signal and the channel estimate.

Providing the feedback signal may include a modified Viterbi equalizer providing an expected corrupted symbol at time index k as the feedback signal at the time index k. Equalizing the corrected signal may include providing a plurality of equalized symbols of the equalized signal by the modified Viterbi equalizer. The modified Viterbi equalizer may have a traceback length (TL), where TL is an integer greater than one and the plurality of equalized symbols are provided at time index k+TL. The modified Viterbi equalizer may have a plurality of states. The plurality of states may be associated with corresponding accumulated path metrics. The expected corrupted symbol may correspond to a most likely state selected from the plurality of states based on the corresponding accumulated path metrics at the time index k.

Providing the feedback signal may include convolving an instant decision symbol of a modified Viterbi equalizer at time index k with the channel estimate. Equalizing the corrected signal may include providing a plurality of equalized symbols of the equalized signal by the modified Viterbi equalizer. The modified Viterbi equalizer may have a traceback length (TL), where TL is an integer greater than one and the plurality of equalized symbols are provided at time index k+TL. The modified Viterbi equalizer may have a plurality of states. The plurality of states may be associated with corresponding accumulated path metrics. The instant decision symbol may correspond to a most likely state selected from the plurality of states based on the corresponding accumulated path metrics at the time index k.

Providing the feedback signal may include slicing the corrected signal at time index k to generate a sliced corrected symbol and convolving the sliced corrected symbol with the channel estimate to generate a symbol of the feedback signal at time index k. Equalizing the corrected signal may include providing a plurality of equalized symbols by a Viterbi equalizer having a traceback length (TL), where TL is an integer greater than one and the plurality of equalized symbols are provided at time index k+TL.

In at least one embodiment, a wireless communications receiver includes an error correction circuit configured to compensate for a frequency or phase offset in a baseband version of a received radio frequency signal and to generate a corrected signal based on the baseband version of the received radio frequency signal and a feedback signal. The wireless communications receiver includes a Viterbi equalizer configured to generate an equalized received signal based on the corrected signal and a channel estimate. The feedback signal is generated based on the corrected signal and the channel estimate.

The Viterbi equalizer may be configured to provide an expected corrupted symbol at time index k as the feedback signal at the time index k, and may be configured to provide a plurality of equalized symbols of the equalized received signal. The Viterbi equalizer may have a traceback length (TL), where TL is an integer greater than one and may provide the plurality of equalized symbols at time index k+TL. The Viterbi equalizer may have a plurality of states. The plurality of states may be associated with corresponding accumulated path metrics. The expected corrupted symbol may correspond to a most likely state selected from the plurality of states based on the corresponding accumulated path metrics at the time index k.

The wireless communications receiver may include a circuit configured to convolve an instant decision symbol of the Viterbi equalizer at time index k with the channel estimate. The Viterbi equalizer may have a traceback length (TL), where TZ is an integer greater than one and may be configured to provide a plurality of equalized symbols of the equalized received signal at time index k+TL. The Viterbi equalizer may have a plurality of states associated with corresponding accumulated path metrics, and the instant decision symbol may correspond to a most likely state selected from the plurality of states based on the corresponding accumulated path metrics at the time index k.

The wireless communications receiver may include a slicer circuit configured to slice the corrected signal at time index k to generate a sliced corrected symbol. The wireless communications receiver may include a feedback circuit configured to generate the feedback signal at the time index k based on a convolution of the sliced corrected symbol with the channel estimate. The Viterbi equalizer may have a traceback length (TL), where TL is an integer greater than one, and may be configured to provide a plurality of equalized symbols at time index k+TL.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a functional block diagram of an exemplary wireless communications system.

FIG. 2 illustrates a functional block diagram of an exemplary receiver of the exemplary wireless communications receiver of FIG. 1.

FIG. 3 illustrates a functional block diagram of a demodulator including a Kalman filter-based PLL.

FIG. 4 illustrates a functional block diagram of a Kalman filter-based PLL using Cartesian coordinates to generate an error signal.

FIG. 5 illustrates a functional block diagram of a Kalman filter-based PLL using polar coordinates to generate an error signal.

FIG. 6 illustrates a functional block diagram of a demodulator including a Kalman filter-based PLL coupled to a modified Viterbi equalizer.

FIG. 7A illustrates a functional block diagram of an integrated Kalman filter-based PLL and Viterbi equalizer.

FIG. 7B illustrates a functional block diagram of an integrated Kalman filter-based PLL and modified Viterbi equalizer.

FIG. 7C illustrates a functional block diagram of another embodiment of an integrated Kalman filter-based PLL and modified Viterbi equalizer.

FIG. 8 illustrates signals of FIG. 7C represented mathematically as a function of time index k.

FIG. 9 illustrates a trellis diagram for an exemplary modified Viterbi equalizer of FIG. 7C.

FIG. 10 illustrates pseudocode for an exemplary modified Viterbi equalizer of FIGS. 7C, 8, and 9.

The use of the same reference symbols in different drawings indicates similar or identical items.

### DETAILED DESCRIPTION

A technique for reducing ISI, frequency offset, and phase offset in a demodulator of a wireless communications system includes integrating a Kalman filter-based PLL and a Viterbi equalizer. The integrated Kalman filter-based PLL and Viterbi equalizer includes a Kalman filter-based PLL that provides a frequency or phase offset corrected signal to a modified Viterbi equalizer and the modified Viterbi equalizer provides a reference signal to the Kalman filter-based PLL for use in determining phase error. In an embodiment, the reference signal is based on an instant decision of the modified Viterbi equalizer rather than waiting for an entire traceback length of time to receive an MLSE equalized symbol for use as the reference symbol by the Kalman filter-based PLL.

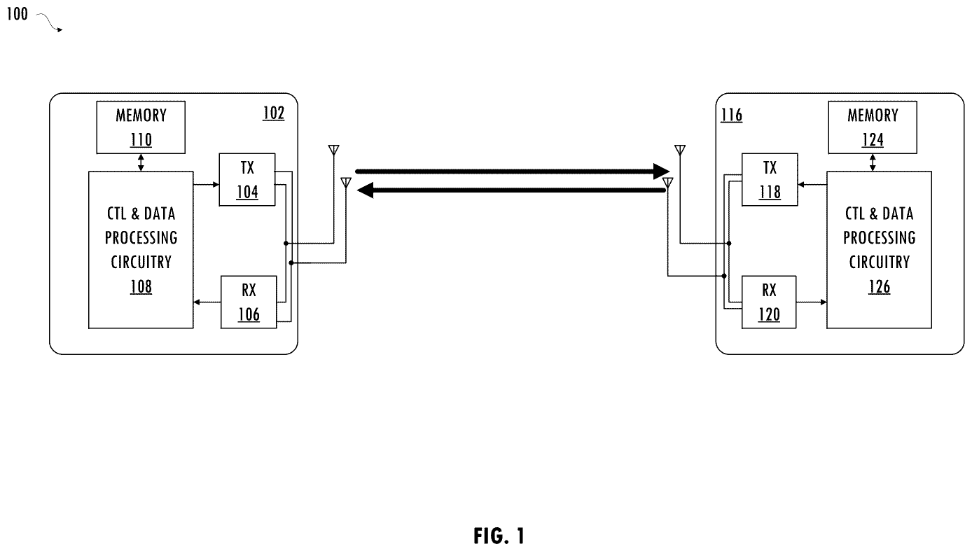

Referring to FIG. 1, in at least one embodiment, wireless communications system 100 includes wireless communications device 102 and wireless communications device 116, which are devices compliant with the BLE communications protocol or BLE HDT communications protocol designed for low power and low latency applications. Wireless communications device 102 includes transmitter 104, receiver 106, control & data processing circuitry 108, and memory 110. Wireless communications device 116 includes transmitter 118, receiver 120, control & data processing circuitry 126, and memory 124. Although wireless communications device 102 and wireless communications device 116 are illustrated as each including only one transmitter, one receiver, and two antennas, in other embodiments of wireless communications system 100, wireless communications device 102 or wireless communications device 116 includes multiple transmitters, multiple receivers, additional antennas, or a single antenna with internal circuitry selection or radio frequency switches. Wireless communications system 100 can communicate information using a predetermined wireless communications protocol, e.g., data using BLE communications protocol or BLE HDT communications protocol. However, in other embodiments, wireless communications system 100 can transmit and receive data compliant with other wireless communications protocols.

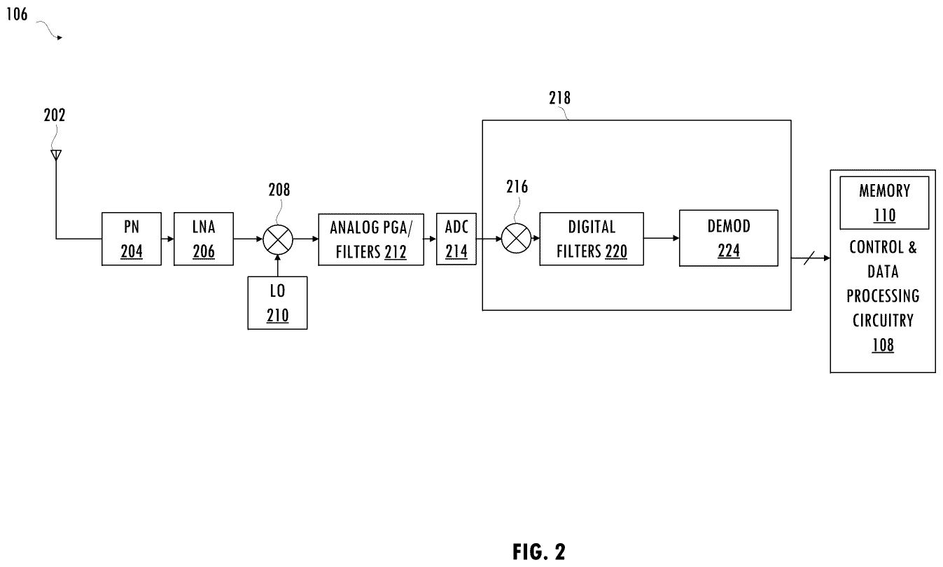

FIG. 2 illustrates an exemplary embodiment of receiver 106 that may be included in the wireless communications devices described above. Antenna 202 provides a radio frequency (RF) signal to passive network 204, which provides impedance matching, filtering, and electrostatic discharge protection. Passive network 204 is coupled to low-noise amplifier 206, which amplifies the RF signal without substantial degradation to the signal-to-noise ratio and provides the amplified RF signal to frequency mixer 208. Frequency mixer 208 performs frequency translation or shifting of the RF signal using a reference or local oscillator signal provided by local oscillator 210. For example, in at least one operational mode of receiver 106, frequency mixer 208 translates the RF signal from a 2.4 GHz frequency band to baseband frequencies centered at DC (i.e., zero-intermediate frequency (ZIF) in a ZIF mode of operation). In another operational mode, receiver 106 is configured as a low-intermediate frequency (LIF) receiver (i.e., in a LIF mode of operation) and frequency mixer 208 translates the RF signal to a low-intermediate frequency (e.g., 100-200 kHz) to reduce or eliminate DC offset and 1/f noise problems of ZIF receivers.

Frequency mixer 208 provides the translated output signal as a set of two signals, an in-phase (I) signal and a quadrature (Q) signal. The I and Q signals are analog time-domain signals. In at least one embodiment of receiver 106, the analog programmable gain amplifier and filters 212 provide amplified and filtered versions of the I and Q signals to analog-to-digital converter (ADC) 214, which converts those versions of the I and Q signals to digital I and Q signals (i.e., I and Q samples). Exemplary embodiments of ADC 214 use a variety of signal conversion techniques (e.g., delta-sigma (i.e., sigma-delta) analog-to-digital conversion). ADC 214 provides the digital I and Q signals to signal processing circuitry 218. In general, signal processing circuitry 218 performs digital signal processing (e.g., frequency translation (e.g., using digital mixer 216), filtering (e.g., using digital filters 220), demodulation, or signal correction) of the digital I and Q signals. In at least one embodiment, signal processing circuitry 218 includes demodulator 224, which recovers or extracts information from digital I and Q signals (e.g., data signals, which were modulated using phase-shift keying or quadrature amplitude modulation).

Control & data processing circuitry 108 may perform a variety of functions (e.g., logic, arithmetic, etc.). For example, control & data processing circuitry 108 may use the demodulated data in a program, routine, or algorithm (whether in software, firmware, hardware, or a combination thereof) to perform desired control or data processing tasks. In at least one embodiment, control & data processing circuitry 108, which includes memory 110, controls other circuitry, sub-system, or systems (not shown). In an embodiment, control & data processing circuitry 108 implements a data link layer that includes a state machine, defines state transitions, defines packet formats, performs scheduling, performs radio control, and provides link-layer decryption consistent with at least one wireless communications protocol. Receiver 106 is illustrative only and may vary with the communications protocol implemented by wireless communications system 100 of FIG. 1.

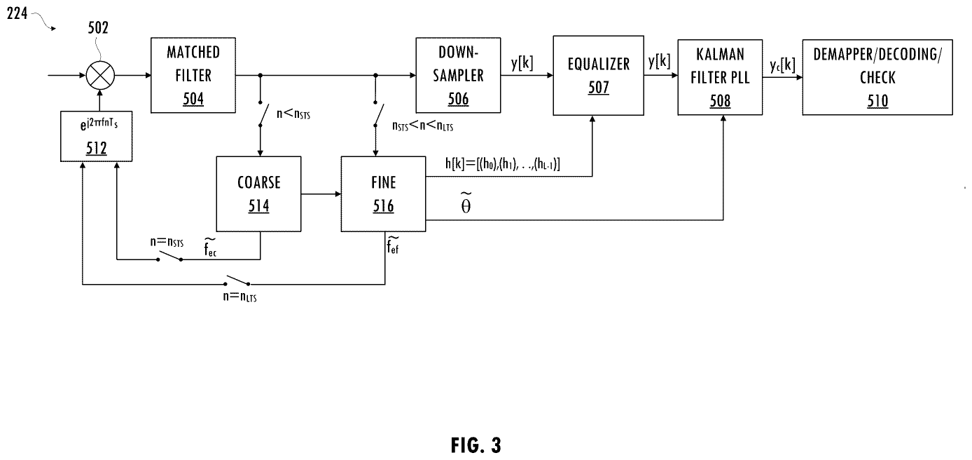

Referring to FIG. 3, in at least one embodiment, demodulator 224 receives a digital intermediate frequency signal and digital mixer 502 frequency shifts the signal to baseband (e.g., ZIF) using a reference signal provided by signal generator 512. Under ideal conditions, the baseband signal provided by mixer 502 is perfectly centered around DC. However, mismatch between the remote oscillator of the transmitting wireless communications device and the local oscillator of the receiving wireless communications device causes a frequency or phase offset in the baseband signal. Matched filter 504 increases the signal-to-noise ratio of the received signal but introduces a delay. During a first phase of receiver processing (e.g., during a short training sequence of a preamble sequence, i.e., n<n_{STS}), coarse timing detection and frequency estimation 514 generates a coarse frequency correction [symbol] to reduce the frequency offset. During a second phase of receiver processing (e.g., during a long training sequence of preamble sequence, i.e., n_{STS}<n≤n_{LTS}), fine timing detection and frequency and phase estimation 516 generates fine frequency error correction [symbol] and initial phase estimate \tilde{θ} to further reduce the frequency or phase offset. The fine timing detection and frequency and phase estimation 516 also generates and supplies channel estimate h to equalizer 507, which in an embodiment includes a Linear Minimum Mean Squared Error (LMMSE) equalizer.

In an embodiment of demodulator 224, mixer 502 digitally mixes the received signal with the reference signal (e.g., a tone having a programmable frequency) generated by signal generator 512. Prior to detecting the short training sequence (i.e., n<n_{STS}), signal generator 512 is programmed to generate an intermediate frequency tone having frequency f_{if}, which is used to down convert the received signal to baseband or DC using mixer 502. After detecting the short training sequence, but before detecting the long training sequence (i.e., n_{STS}<n≤n_{LTS}), signal generator 512 is programmed to a coarsely corrected value having frequency f_{if}+ [symbol] to further down-convert the received signal and compensate for frequency offset. After detecting the long training sequence (i.e., n>n_{LTS}), signal generator 512 is programmed to a finely corrected value having frequency f_{if}+ [symbol] + [symbol] . Signal generator 512 adjusts the reference signal by coarse frequency correction [symbol] , or fine frequency correction [symbol] , and thus, mixer 502 applies error correction to the received signal. Downsampler 506 generates received signal y[k], which is a version of the received signal that is downsampled from a sample space to a symbol space, and supplies received signal y[k] to equalizer 507. Kalman filter-based PLL 508, described in detail below, applies initial phase estimate \tilde{θ} to the received signal and reduces or eliminates any residual phase error to generate corrected received signal y_{c}[k], which is a phase-corrected version of received signal y[k].

Demapper/decoding/check circuit 510 recovers transmitted data from corrected received signal y_{c}[k] using demapping, decoding, and error correction techniques known in the art.

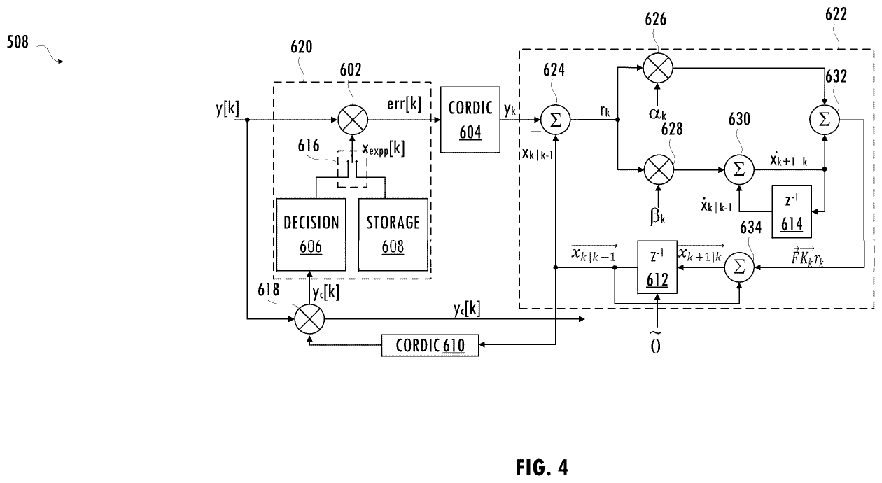

Referring to FIG. 4, in at least one embodiment, Kalman filter-based PLL 508 includes phase detector 620 and Kalman filter 622. In at least one embodiment, phase detector 620 multiplies received signal y[k] by a complex conjugate of a reference signal, i.e., expected signal xₑₓₚₚ[k], to extract any frequency offset or phase offset and generate error signal err[k]. In at least one embodiment, phase detector 620 includes select circuit 616, which selectively provides a predetermined signal, e.g., a signal based on the Access Address field of a BLE packet, as expected signal xₑₓₚₚ[k] to multiplier 602 at time index k. For example, if k≤n_{AAEND}, then select circuit 616 provides a corresponding output of storage 608, e.g., samples of the predetermined Access Address (in Cartesian coordinates, i.e., real and imaginary values corresponding to the in-phase and quadrature values) as expected signal xₑₓₚₚ[k]. If k>n_{AAEND}, then select circuit 616 provides the output of decision circuit 606 as expected signal xₑₓₚₚ[k]. In general, all BLE packets include the Access Address to identify communications on a physical channel, and to allow a receiver to exclude or ignore packets on different physical channels that are using the same physical interface channels in physical proximity.

In at least one embodiment, decision circuit 606 generates expected signal xₑₓₚₚ[k], which is used as a reference signal, by comparing a corrected version of the received signal to predetermined modulated values and provides the nearest predetermined modulated value (in Cartesian coordinates, i.e., real and imaginary values corresponding to the in-phase and quadrature values) as expected signal xₑₓₚₚ[k]. In general, decision circuit 606 performs a slicing operation that maps the corrected version of the received signal, which includes noise, to the closest noise-free constellation point of the applicable modulation scheme (e.g., the constellation point of the applicable modulation scheme having the minimum Euclidian distance to the corrected received signal y_{c}[k]).

In at least one embodiment, COordinate Rotation DIgital Computer (CORDIC) 604 converts error signal err[k] from Cartesian coordinates to polar coordinates using a CORDIC, which may be dedicated to a phase measurement implementation or shared with other operations of the receiver. In general, a CORDIC implements known techniques to perform calculations, including trigonometric functions (e.g., an arctangent function) and complex multiplies, without using a multiplier. For example, the only operations the CORDIC uses are addition, subtraction, bit-shift, and table-lookup operations to implement the arctangent function. In other embodiments, a digital signal processor executing firmware or an arctangent circuit is used to convert error signal err[k] from Cartesian coordinates to polar coordinates.

In an embodiment, since the Kalman filter only affects phase, CORDIC 604 provides only the phase component of phase error signal err[k], as the input to Kalman filter 622. Kalman filter 622 determines residual phase error signal rₖ by computing the difference between phase yₖ and predicted instantaneous phase x_{k|k-1}. Phase difference circuit 624 provides residual phase error signal rₖ to a proportional integral time-invariant controller including a proportional path (represented by gain circuit 626) and an integral path (represented by gain circuit 628, accumulator 630, and register 614). Summing circuit 632 combines the outputs of the proportional path and the integral path and provides a predicted frequency signal to an integrator represented by accumulator 634 and register 612. The integrator provides the predicted instantaneous phase signal, x̅_̅{̅(̅k̅|̅k̅-̅1̅)̅}̅, to phase difference circuit 624 and to CORDIC 610, which converts the predicted instantaneous phase signal from polar coordinates to Cartesian coordinates for use as an error correction signal to be combined with received signal y[k] by correction circuit 618 to generate corrected received signal y_{c}[k].

In an embodiment, Kalman filter-based PLL 508 can be modeled by defining a state

$$\vec{{x}_{k}} = [ \begin{matrix}{x}_{k} \\ \dot{{x}_{k}}\end{matrix} ] ,$$

where xₖ is instantaneous phase and \dot{x}ₖ is frequency. The state transition model is

$$\vec{{x}_{k + 1}} = \vec{F} \vec{{x}_{k}} + \vec{{W}_{k}} = [ \begin{matrix}1 & 1 \\ 0 & 1\end{matrix} ] [ \begin{matrix}{x}_{k} \\ \dot{{x}_{k}}\end{matrix} ] + [ \begin{matrix}{w}_{k} \\ \dot{{w}_{k}}\end{matrix} ] .$$

The observation model is

$${y}_{k} = \vec{H} \vec{{x}_{k}} + {v}_{k} = [ \begin{matrix}1 & 0\end{matrix} ] [ \begin{matrix}{x}_{k} \\ \dot{{x}_{k}}\end{matrix} ] + {v}_{k} = {x}_{k} + {v}_{k} .$$

The prediction model is

$$\vec{{x}_{( k \vert k - 1 )}} = [ \begin{matrix}{x}_{( k \vert k - 1 )} \\ \dot{{x}_{( k \vert k - 1 )}}\end{matrix} ] ; and$$

$$\vec{{x}_{( k + 1 \vert k )}} = \vec{F} \vec{{x}_{( k \vert k - 1 )}} + \vec{F} \vec{{K}_{k}} {r}_{k} ,$$

where \vec{F} is the state transition matrix, \vec{H} is the observation matrix, vₖ is the phase variance, \vec{K}ₖ is the loop gain vector

$$[ \begin{matrix}{α}_{k} \\ {β}_{k}\end{matrix} ] ,$$

rₖ is the error that drives or controls the prediction, and rₖ=yₖ+\vec{HX_{(k|k-1)}}. Register 612 is initialized with initial phase estimate \tilde{θ}, which is provided by fine timing detection and frequency and phase estimation 516 of FIG. 3.

Referring to FIG. 4, for an exemplary received signal y[k]=e^{j(θ}^{ₘ}^{+2πf}^{_{OS}}^{k+θ}^{ᵤ}⁾, where θₘ is the modulated phase for phase-shift keying, fOS is the frequency offset between the remote oscillator of the transmitter and the local oscillator of the receiver, and θᵤ is a random phase offset, the following table illustrates exemplary signal values, where the first two symbols (time indices of k=1 and k=2) correspond to predetermined Access Address values, and the following three symbols (time indices of k=3, 4, and 5) correspond to data symbols.

| y[k] | xₚ[k] | err[k] | yₖ | x_{k\|k-1} | y_{c}[k] |
|---|---|---|---|---|---|
| ${e}^{j \frac{π}{4} + 2 {π10}^{3} ( 1 ) + \frac{π}{5}}$ | ${e}^{j \frac{π}{4}}$ | ${e}^{j ( 2 {π10}^{3} ( 1 ) + \frac{π}{5} )}$ | $2 {π10}^{3} ( 1 ) + \frac{π}{5}$ | $2 {π10}^{3} ( 1 ) + \frac{π}{5} + \frac{π}{100}$ | NA (AA) |
| ${e}^{j \frac{3 π}{4} + 2 {π10}^{3} ( 2 ) + \frac{π}{5}}$ | ${e}^{j \frac{3 π}{4}}$ | ${e}^{j ( 2 {π10}^{3} ( 2 ) + \frac{π}{5} )}$ | $2 {π10}^{3} ( 2 ) + \frac{π}{5}$ | $2 {π10}^{3} ( 2 ) + \frac{π}{5} + \frac{π}{100} - \frac{π}{150}$ | NA (AA) |
| ${e}^{- j \frac{π}{4} + 2 {π10}^{3} ( 3 ) + \frac{π}{5}}$ | ${e}^{- j \frac{π}{4}}$ | ${e}^{j ( 2 {π10}^{3} ( 3 ) + \frac{π}{5} )}$ | $2 {π10}^{3} ( 3 ) + \frac{π}{5}$ | $2 {π10}^{3} ( 3 ) + \frac{π}{5} - \frac{π}{150}$ | ${e}^{- j \frac{π}{4} - \frac{π}{150}}$ |
| ${e}^{- j \frac{π}{4} + 2 {π10}^{3} ( 4 ) + \frac{π}{5}}$ | ${e}^{- j \frac{π}{4}}$ | ${e}^{j ( 2 {π10}^{3} ( 4 ) + \frac{π}{5} )}$ | $2 {π10}^{3} ( 4 ) + \frac{π}{5}$ | $2 {π10}^{3} ( 4 ) + \frac{π}{5} - \frac{π}{120}$ | ${e}^{- j \frac{π}{4} - \frac{π}{120}}$ |
| ${e}^{- j 3 \frac{π}{4} + 2 {π10}^{3} ( 5 ) + \frac{π}{5}}$ | ${e}^{- j \frac{3 π}{4}}$ | ${e}^{j ( 2 {π10}^{3} ( 5 ) + \frac{π}{5} )}$ | $2 {π10}^{3} ( 5 ) + \frac{π}{5}$ | $2 {π10}^{3} ( 5 ) + \frac{π}{5} - \frac{π}{90}$ | ${e}^{- j \frac{3 π}{4} - \frac{π}{90}}$ |

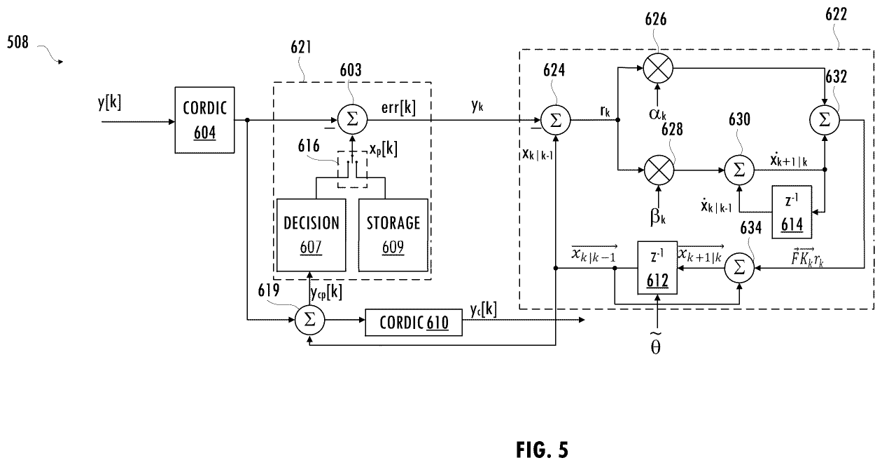

Referring to FIG. 5, in other embodiments of Kalman filter-based PLL 508, the conversions between Cartesian coordinates and polar coordinates are performed outside of the loop, thereby decreasing computational complexity of Kalman filter-based PLL 508. Decision circuit 607 and storage 609 provide outputs (e.g., a binary quantization of a demodulated signal and predetermined Access Address symbols, respectively) in polar coordinates. CORDIC 604 and CORDIC 610 perform the conversions between Cartesian coordinates and polar coordinates outside of the loop. Instead of performing complex multiplications, as required by the embodiment described above, phase detector 621 uses adder 603 to generate error signal err[k] based on the reference signal provided by decision circuit 607 or storage circuit 609 to determine the phase error and the loop performs correction using adder 619. CORDIC 604 converts received signal y[k] from Cartesian coordinates to polar coordinates and CORDIC 610 converts the corrected signal from polar coordinates to Cartesian coordinates to generate corrected received signal y_{c}[k].

To improve performance of demodulator 244, conventional LMMSE equalization is replaced with MLSE equalization. However, to realize the performance advantages of the MLSE equalization and the performance advantages of the Kalman filter-based PLL, a demodulator architecture integrates the equalization and Kalman filter-based PLL functions. Tn integrated Kalman filter-based PLL and Viterbi equalizer provides the Kalman filter-based PLL with a reference signal that incorporates an estimate of the ISI that is included in the received baseband signal and the Viterbi equalizer receives symbols that have been compensated for frequency or phase offset in the received baseband signal.

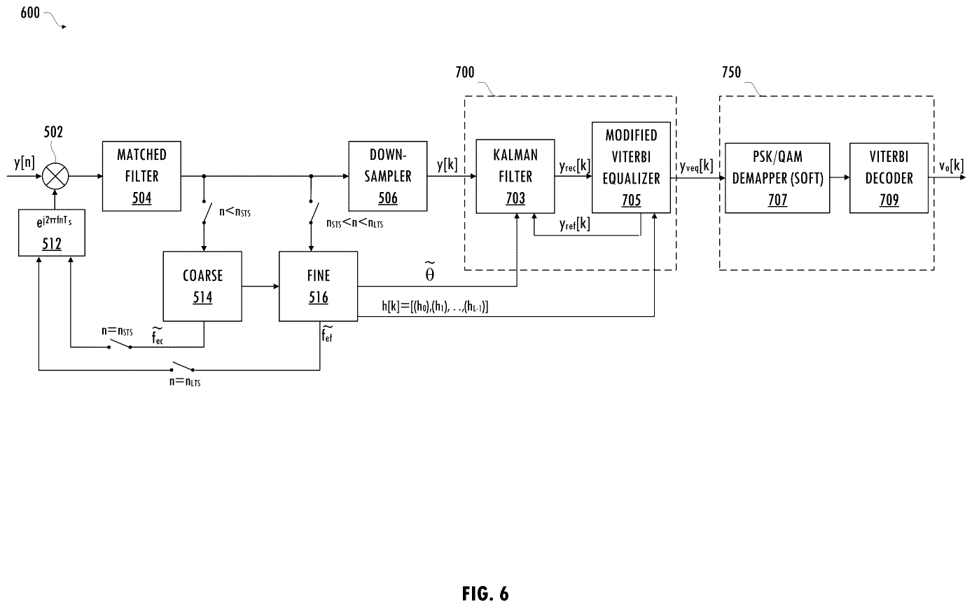

Referring to FIG. 6, in at least one embodiment, demodulator 600 includes integrated Kalman filter and Viterbi equalizer 700, which implements an MLSE equalizer using the Viterbi algorithm and reduces or eliminates ISI in the signal received by the Kalman filter-based PLL by using a reference signal that incorporates an estimate of the ISI. In some embodiments of integrated Kalman filter and Viterbi equalizer 700, that reference signal generated by a modified Viterbi equalizer. A Kalman filter-based PLL provides, to the modified Viterbi equalizer, symbols that are compensated for frequency or phase offset. For example, Kalman filter-based PLL 703 provides frequency or phase offset compensated signal y_{rec}[k] to modified Viterbi equalizer 705 and modified Viterbi equalizer 705 provides to Kalman filter-based PLL 703 reference signal y_{ref}[k], which incorporates an estimate of the ISI and is used by to determine phase error. In an embodiment, rather than waiting for an entire traceback length of modified Viterbi equalizer 705 to use equalized symbols to generate a reference signal for the Kalman filter-based PLL, modified Viterbi equalizer 705 provides a symbol corresponding to an instant decision for use as the reference symbol. Accordingly, demodulator 600 addresses inter-symbol interference from a multi-path fading channel and has improved phase tracking and channel equalization characteristics as compared to the demodulator described above. In an embodiment, integrated Kalman filter and Viterbi equalizer 700 provides equalized received signal y_{veq}[k] to demapper and decoder 750. In at least one embodiment, demapper and decoder 750 includes a phase-shift keying or quadrature amplitude modulation demapper 707 and Viterbi decoder 709, which provides decoded output vₒ[k].

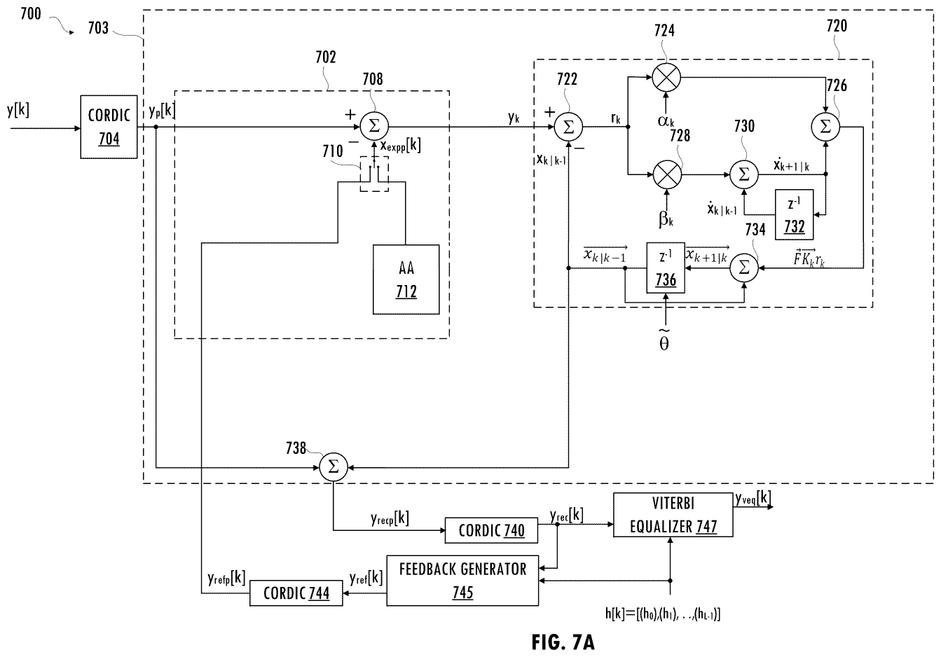

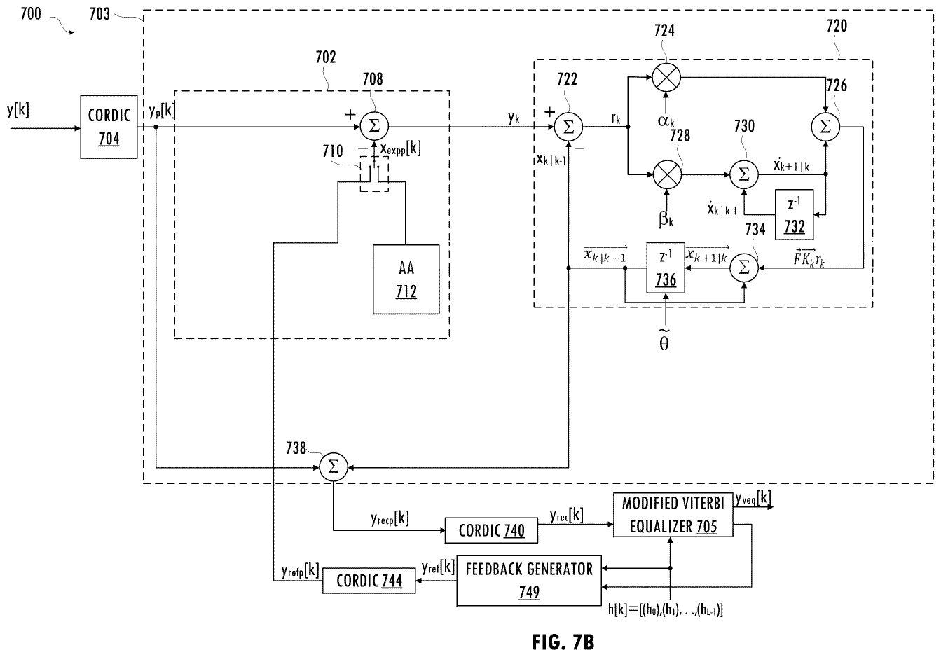

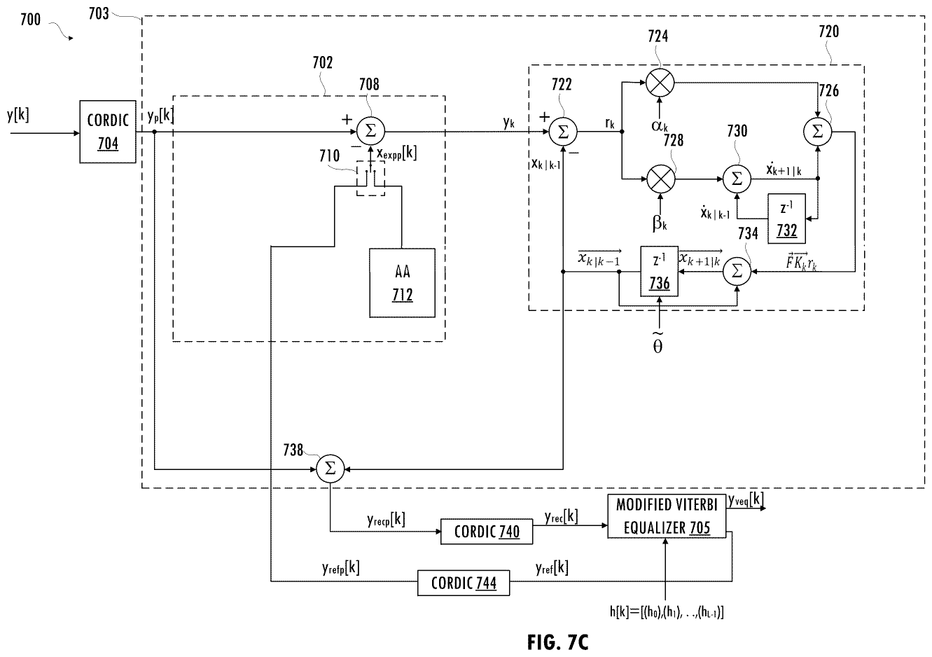

Referring to FIGS. 7A, B, and C, a Kalman filter-based PLL is coupled in series with a Viterbi equalizer. The Kalman filter-based PLL compensates for frequency or phase offset in the received signal and provides frequency or phase offset corrected symbols to the Viterbi equalizer. The Viterbi equalizer receives channel estimate h[k] and a reference signal for the Kalman filter-based PLL is generated based on channel estimate h[k] and frequency or phase offset compensated signal y_{rec}[k].

In at least one embodiment, integrated Kalman filter and Viterbi equalizer 700 receives received signal y[k] in Cartesian coordinates and uses CORDIC 704 to convert received signal y[k] into polar coordinates (i.e., received signal yₚ[k]). CORDIC 704 provides received signal yₚ[k] to phase detector 702. The phase component of received signal yₚ[k] is a combination of transmitted phase information θ[k] and phase error φ. By computing the difference between the phase component of the received signal and the expected value of the phase component θₑ[k], phase yₖ is generated and provided as an input to Kalman filter 720.

Kalman filter 720 determines residual phase error signal rₖ by computing the difference between phase yₖ and predicted instantaneous phase x_{k|k-1}. Phase difference circuit 722 provides residual phase error signal rₖ to a proportional integral time-invariant controller including a proportional path (represented by gain circuit 724) and an integral path (represented by gain circuit 728, accumulator 730, and register 732). Summing circuit 726 combines the outputs of the proportional path and the integral path and provides a predicted frequency signal to an integrator represented by accumulator 734 and register 736. The integrator provides the predicted instantaneous phase signal, \vec{x_{(k|k-1)}}, to phase difference circuit 722 and to error correction circuit 738, which provides a frequency or phase offset compensated signal in polar coordinates to CORDIC 740, which converts the frequency or phase offset compensated signal y_{recp}[k] from polar coordinates to Cartesian coordinates (i.e. frequency or phase offset compensated signal y_{rec}[k]), which is then MLSE equalized using a Viterbi equalizer to generate equalized received signal y_{veq}[k].

In an embodiment, the Kalman filter-based PLL can be modeled by defining a state

$$\vec{{x}_{k}} = [ \begin{matrix}{x}_{k} \\ \dot{{x}_{k}}\end{matrix} ] ,$$

where xₖ is instantaneous phase and \dot{x}ₖ is frequency. The state transition model is

$$\vec{{x}_{( k + 1 )}} = \vec{F} \vec{{x}_{k}} + \vec{{W}_{k}} = [ \begin{matrix}1 & 1 \\ 0 & 1\end{matrix} ] [ \begin{matrix}{x}_{k} \\ \dot{{x}_{k}}\end{matrix} ] + [ \begin{matrix}{w}_{k} \\ \dot{{w}_{k}}\end{matrix} ] .$$

The observation model is

$${y}_{k} = \vec{H} \vec{{x}_{k}} + {v}_{k} = [ \begin{matrix}1 & 0\end{matrix} ] [ \begin{matrix}{x}_{k} \\ \dot{{x}_{k}}\end{matrix} ] + {v}_{k} = {x}_{k} + {v}_{k} .$$

The prediction model is

$$\vec{{x}_{( k \vert k - 1 )}} = [ \begin{matrix}{x}_{( k \vert k - 1 )} \\ {x}_{( k \vert \dot{k} - 1 )}\end{matrix} ] ;$$

$$and$$

$$\vec{{x}_{( k + 1 \vert k )}} = \vec{F} \vec{{x}_{( k \vert k - 1 )}} + \vec{F} \vec{{K}_{k}} {r}_{k} ,$$

where \vec{F} is the state transition matrix, \vec{A} is the observation matrix, vₖ is the phase variance, \vec{K}ₖ is the loop gain vector

$$[ \begin{matrix}{α}_{k} \\ {β}_{k}\end{matrix} ] ,$$

rₖ is the residual phase error that drives or controls the prediction, and rₖ=yₖ+\vec{HX_{(k|k-1)}}. Register 736 is initialized with initial phase estimate \tilde{θ}, which is provided by fine timing detection and frequency and phase estimation 516. In other embodiments, rather than perform the conversion from Cartesian coordinates to polar coordinates outside the loop, integrated Kalman filter and Viterbi equalizer 700 replaces phase difference circuit 708 and error correction circuit 738 with complex multipliers and converts from Cartesian coordinates to polar coordinates inside the loop, similar to the embodiment of FIG. 4.

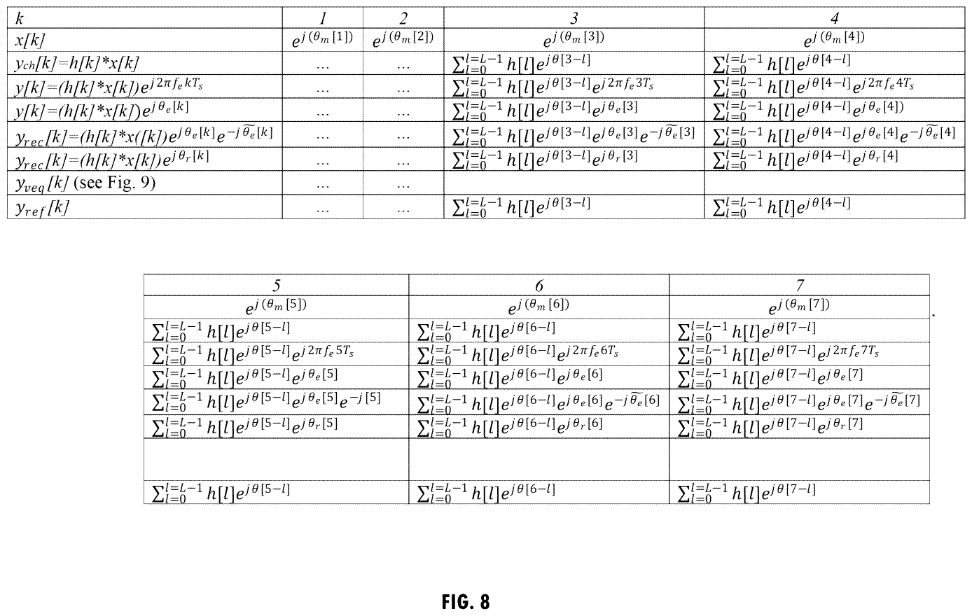

Referring to FIGS. 7A, 7B, 7C, 8, and 9, for an exemplary transmitted symbol x[k], a received symbol at the input of a receiving device is y_{ch}[k]=h[k]*x[k], where h[k] is the transfer function corresponding to the transmission channel that introduces ISI, and where * represents a convolution operation. Exemplary signal values for the first two symbols (time indices of k=1 and k=2) correspond to predetermined Access Address values, and exemplary signal values for the following five symbols (time indices of k=3, 4, 5, 6, and 7) correspond to data symbols, where θₘ is the modulated phase for phase-shift keying. For example, in an embodiment having a channel length, L, of 3,

$$h [ k ] = [ ( {h}_{0} ) , ( {h}_{1} ) , ( {h}_{2} ) ] ;$$

$$y [ k ] = ( {h}_{0} x [ k - 1 ] + {h}_{1} x [ k ] + {h}_{2} x [ k + 1 ] ) {e}^{j 2 π {f}_{e} k {T}_{s}} ,$$

$$and$$

$$y [ k ] = {e}^{j ϕ [ k ]} {θ}_{e} [ k ] ,$$

$$where$$

$${e}^{j ϕ [ k ]} = ( {h}_{0} x [ k - 1 ] + {h}_{1} x [ k ] + {h}_{2} x [ k + 1 ] ) ,$$

and
θₑ[k], is phase error to be recovered, where θₑ[k]=e^{j2πf}^{ₑ}^{kT}^{ₛ}, fₑ is frequency offset, and Tₛ is the symbol period. In an embodiment, error correction circuit 738 receives the entire polar representation of y[k]. However, since the Kalman filter only affects phase, other embodiments of phase detector 702 receive only a phase component of a reference signal and φ[k]+θₑ[k], which is the phase portion of the polar representation of y[k], and where φ[k] is the transmitted phase with ISI. The output of CORDIC 740 is the frequency and phase-error-corrected symbol in Cartesian coordinates:

$${y}_{r e c} [ k ] = ( h [ k ] ⋆ x ( [ k ] ) {e}^{j {θ}_{e} [ k ]} {e}^{- j \tilde{{θ}_{e}} [ k ]} ,$$

which can be represented as

$${y}_{r e c} [ k ] = ( h [ k ] ⋆ x [ k ] ) {e}^{j {θ}_{r} [ k ]} ,$$

where θᵣ[k], is the residual phase error (i.e., the estimation error), and where θₑ[k] is the estimated phase error in the Kalman filter. Viterbi equalizer 705 and modified Viterbi equalizer 705 equalize the frequency or phase offset compensated signal to generate equalized signal y_{veq}[k], which is generated using conventional Viterbi equalization techniques. In addition, reference signal y_{ref}[k] is generated and converted into polar coordinates by CORDIC 744. CORDIC 744 provides the reference signal y_{ref}[k] to select circuit 710 for use as expected signal xₑₓₚₚ[k]. In at least one embodiment, select circuit 710, selectively provides to phase difference circuit 708 a predetermined signal, e.g., a signal based on the Access Address field of a BLE packet, as expected signal xₑₓₚₚ[k] according to sample index k, as described above. For example, if k≤n_{AAEND}, then select circuit 710 provides a corresponding output of Access Address storage 712, e.g., samples corresponding to the predetermined Access Address (in polar coordinates, i.e., phase) for use as expected signal xₑₓₚₚ[k]. Those samples are generated by convolving the predetermined Access Address symbols with channel estimate h[k] after channel estimate h[k] is generated but before providing symbols to the Kalman filter. If k>n_{AAEND}, then select circuit 710 provides the phase of y_{ref}[k] for use as expected signal xₑₓₚₚ[k].

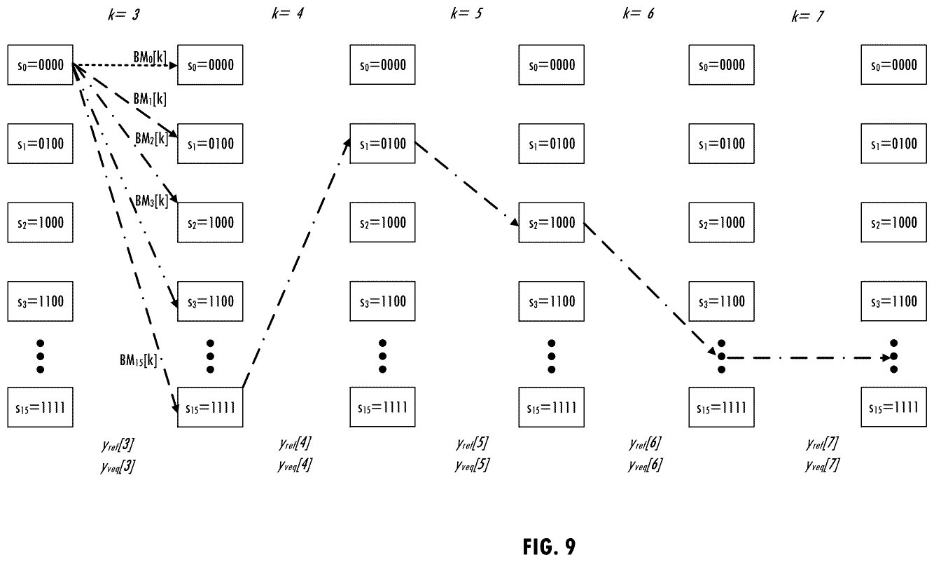

In at least one embodiment, Viterbi equalizer 747 or modified Viterbi equalizer 705 (i.e., the Viterbi equalizer) provides the equalized signal y_{veq}[k] based on the Viterbi algorithm. The trellis diagram of FIG. 9 visually represents all possible state transitions based on the channel's memory and the possible ISI-corrupted symbols. At each stage of the trellis diagram, the Viterbi algorithm calculates a branch metric that represents the likelihood of a specific ISI-corrupted symbol value given the received signal at time index k. The Viterbi algorithm eliminates unlikely paths as it progresses through the trellis and only keeps the most probable sequences based on the calculated branch metrics, thereby significantly reducing computational complexity. Modified Viterbi equalizer 705 provides reference signal y_{ref}[k] or a signal used to generate reference signal y_{ref}[k] in addition to providing equalized signal y_{veq}[k].

In an embodiment, the Viterbi equalizer uses branch metrics (e.g., log-likelihood measure of the probability of a corresponding state transition of a state diagram) and path metrics (e.g., sum of the branch metrics of the branches that a path traverses) to find the most likely transmitted symbols corresponding to the received signal (e.g., by identifying a minimum distance path through a trellis diagram corresponding to maximum likelihood estimation and Viterbi estimation techniques). Each path metric corresponds to a number of errors on a maximum-likelihood path to an associated state and each branch metric corresponds to either a Hamming distance or an Euclidian distance between received and expected sequences for branch metrics. In an embodiment, the Viterbi equalizer computes the Euclidian distance between received and expected ISI-corrupted symbol sequences for branch metrics. The Viterbi equalizer introduces a substantial delay before providing an equalized symbol y_{veq}[k] corresponding to a symbol of received signal y[k].

The traceback length (TL) (i.e., traceback depth or traceback value) of the Viterbi equalizer is related to the delay of the Viterbi equalizer. In general, the traceback length of a Viterbi equalizer is an integer indicating the number of trellis branches used to construct each traceback path. In an embodiment of the Viterbi equalizer, TL is an integer that is predetermined, e.g., based on a guideline in the art of setting TL to five times the constraint length or number of channel taps. The Viterbi equalizer selects the path with the lowest cumulative path metric at time index k. If two paths have equal path metrics, the Viterbi equalizer selects a path arbitrarily. The Viterbi equalizer accumulates branch metrics from state to state to generate the path metrics and outputs symbols corresponding to a decision on the minimum path after the full traceback length TL. Accordingly, a symbol of Viterbi equalized signal y_{veq}[k] corresponding to a symbol of received signal y[k] is not available until at least TL symbol periods (e.g., 50 symbol periods) later, which is prohibitive to the use of equalized symbols in providing a reference signal to the Kalman filter-based PLL.

Referring to FIG. 7A, in at least one embodiment, Viterbi equalizer 747 generates equalized signal y_{veq}[k] based on the Viterbi algorithm, and the kth symbol of equalized signal y_{veq}[k] is available at time index k+TL. Feedback generator 745 generates the reference signal y_{ref}[k] by slicing symbols of the frequency or phase offset compensated signal y_{rec}[k]. In general, a sliced symbol is generated by comparing a symbol of the frequency or phase offset compensated signal y_{rec}[k] to a predetermined symbol and generating an output symbol based on the comparison. Feedback generator 745 convolves the sliced symbols with channel estimate h[k] to generate reference signal y_{ref}[k] and the kth symbol of reference signal y_{ref}[k] is available at time index k.

Referring to FIGS. 7B and 7C, in an embodiment, modified Viterbi equalizer 705 also provides a feedback signal used to generate reference symbol y_{ref}[k]. The feedback signal is based on frequency or phase offset compensated signal y_{rec}[k] that is corrected based on the error between a reference symbol and a baseband version of the received radio frequency signal. The feedback signal is further based on channel estimate h[k]. An embodiment of a modified Viterbi equalizer accumulates branch metrics from state to state over the TL to generate path metrics, but unlike a conventional Viterbi equalizer, the modified Viterbi equalizer outputs a feedback symbol corresponding to a decision for a minimum path made based on the path metrics accumulated to the current symbol time for use as reference symbol y_{ref}[k] or for use in generating reference symbol y_{ref}[k]. The feedback symbol is based on previous decisions and is provided in the same symbol time as a corresponding symbol of frequency or phase offset compensated signal y_{rec}[k].

Referring to FIG. 7B, in an embodiment, modified Viterbi equalizer 705 generates equalized signal y_{veq}[k] based on the Viterbi algorithm, and the kth symbol of equalized signal y_{veq}[k] is available at time index k+TL. In addition, modified Viterbi equalizer 705 provides an instantaneous decision at time index k to feedback generator 749. Feedback generator 749 convolves instantaneous decisions of the Viterbi equalization with channel estimate h[k] to generate reference signal y_{ref}[k] and the kth symbol of reference signal y_{ref}[k] is available at time index k. In an embodiment where h[k] has three channel taps, convolving the last three instantaneous decisions of the Viterbi equalization with channel estimate h[k] to generate the reference signal improves performance of integrated Kalman filter and Viterbi equalizer 700 as compared to using the sliced, frequency or phase offset corrected symbols convolved with channel estimate h[k] of FIG. 7A.

However, embodiments of a Viterbi equalizer calculate all possible combinations of symbols convolved with channel estimate h[k] to generate the branch metrics that are used to determine equalized signal y_{veq}[k]. Accordingly, a more efficient integrated Kalman filter and Viterbi equalizer includes a modified Viterbi equalizer that provides a signal based on those calculations for use as reference signal y_{ref}[k] rather than generating a separate convolution of the instantaneous decisions of the Viterbi equalizer with channel estimate h[k] for use as reference signal y_{ref}[k]. Referring to FIG. 7C, in at least one embodiment, modified Viterbi equalizer 705 generates equalized signal y_{veq}[k] based on the Viterbi algorithm, and the kth symbol of equalized signal y_{veq}[k] is available at time index k+TL. In addition, modified Viterbi equalizer 705 outputs the most-likely ISI-corrupted symbol corresponding to a selected state of the Viterbi algorithm (e.g., xₘₛᵤᵣᵥ[stateₘᵢₙ[k]], which is a state having the minimum branch metric at time index k) as reference signal y_{ref}[k], and the kth symbol of reference signal y_{ref}[k] is available at time index k. This implementation consumes less power and uses fewer cycles in a software implementation or consumes less area in a hardware implementation, as compared to the embodiments of FIGS. 7A and 7B.

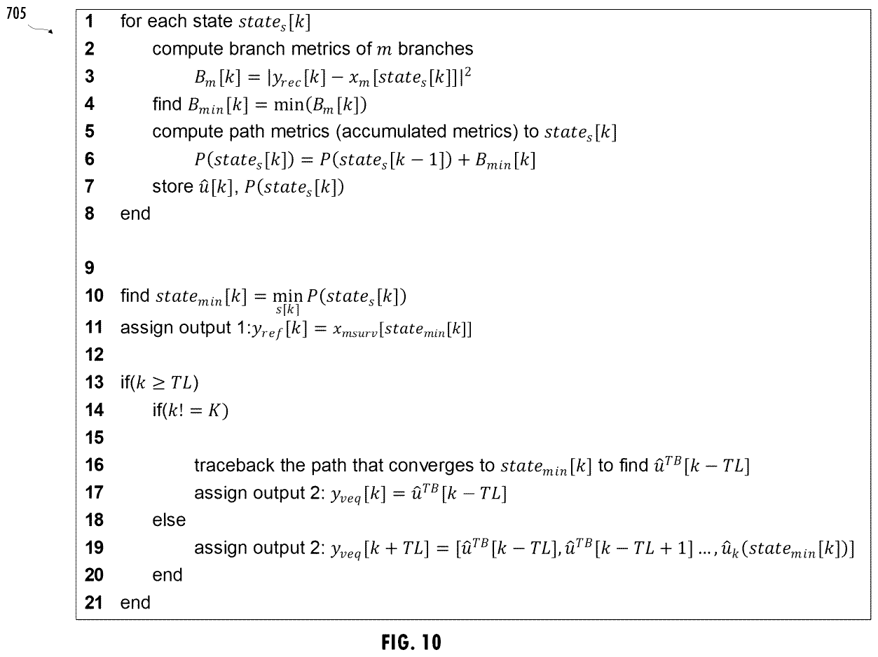

In at least one embodiment, modified Viterbi equalizer 705 provides reference symbol y_{ref}[k], which is the most-likely ISI-corrupted symbol corresponding to a selected state of the Viterbi algorithm (e.g., xₘₛᵤᵣᵥ[stateₘᵢₙ[k]]), and provides the equalized signal y_{veq}[k], based on a frequency or phase offset compensated signal y_{rec}[k], consistent with the pseudocode of FIG. 10, where:
k is the time index;
K is the packet length;
TL is the traceback length;
S is the total number of states of the Viterbi equalizer (e.g., S=2^{(Ntap-1)×N}^{_{bit}}, where Nₜₐₚ is the number of channel taps and N_{bit} is the number of bits per symbol of the modulation format. For example, for a constraint length/number of channel taps of 3, S=2^{(3-1)×2}=16, for QPSK modulation which uses two bits per symbol);
stateₛ[k] is states at time index k, where 0≤s≤S−1;
xₘ[k] is the expected ISI symbol for branch m at time index k from the trellis and is derived based on the channel response, e.g., branch 0 that transits from state₀ to state₁ at time index k would have expected ISI symbol x₀[k]: =h₀×û[k]+h₁Y₀+h₂Y₁ for a channel response with 3 taps and equalized (ISI-free) symbol of [symbol] , where the channel response is h[k]=[(h₀), (h₁), (h₂)], and [Y₀, Y₁] are the symbols corresponding to state₁ for tap 1 and tap 2;
B(m) is the branch metric of branch m;
stateₛ[k−1] is the state at time index k−1 that transits to the current state, stateₛ[k], with least branch metrics;
P(stateₛ[k]) is the path metric accumulated to stateₛ[k];
û[k] is the equalized (ISI free) symbol for stateₛ[k];
stateₘᵢₙ[k] is the state that has minimum path metrics (accumulated metrics) at time index k;
xₘₛᵤᵣᵥ[stateₘᵢₙ[k]] is the expected ISI symbol that corresponds to a surviving branch msurv of survival state (i.e., the state with the minimum path metrics stateₘᵢₙ[k]) at time index k;
û^{TB}[k−TL] is the equalized (ISI-free) symbol associated with the state at time index k−TL on the traceback path.
   Line 11 of the pseudocode of FIG. 10 corresponds to generation of reference symbol y_{ref}[k] of FIG. 7C. In at least one embodiment, y_{ref}[k] is available at time index k, while y_{veq}[k] is available at time index k+TL.

An exemplary receiver for a channel response having three taps (Nₜₐₚ=3) and QPSK modulation (N_{bits}=2) includes a modified Viterbi equalizer corresponding to the trellis diagram of FIG. 9 having three channel taps and 2^{(3-1)×2}=16 states, and TL=15. A corresponding modified Viterbi equalizer provides y_{ref}[3] at time index k=3 and would provide y_{veq}[3] at time index k=15. The modified Viterbi equalizer computes the expected ISI symbol xₘ[k] for the branch metrics computations. For example, expected bits={input_bits, state_bits}={01,0000} has an expected symbol of

$$\{ {e}^{j \frac{3 π}{4}} , {e}^{j \frac{π}{4}} , {e}^{j \frac{π}{4}} \}$$

based on a mapping relationship of

$$00 \to {e}^{j \frac{π}{4}} , 01 \to {e}^{j \frac{3 π}{4}} , 11 \to {e}^{j \frac{- π}{4}} , 10 \to {e}^{j \frac{- π}{4}} .$$

The expected ISI symbols xₘ[k] are computed based on expected bits as follows:
expected

$$bits = \{ 00 , 0000 \} , {x}_{0} [ 3 ] = {e}^{j \frac{π}{4}} {h}_{0} + {e}^{j \frac{π}{4}} {h}_{1} + {e}^{j \frac{π}{4}} {h}_{2} ,$$

and state “0000” transitions to state “0000”;
expected

$$bits = \{ 01 , 0000 \} , {x}_{1} [ 3 ] = {e}^{j \frac{3 π}{4}} {h}_{0} + {e}^{j \frac{π}{4}} {h}_{1} + {e}^{j \frac{π}{4}} {h}_{2} ,$$

and state “0000” transitions to state “0100”;
expected

$$bits = \{ 10 , 0000 \} , {x}_{2} [ 3 ] = {e}^{j \frac{- π}{4}} {h}_{0} + {e}^{j \frac{π}{4}} {h}_{1} + {e}^{j \frac{π}{4}} {h}_{2} ;$$

and state “0000” transitions to state “1000”; . . . ; and
expected

$$bits = \{ 11 , 0000 \} , {x}_{15} [ 3 ] = {e}^{j \frac{- 3 π}{4}} {h}_{0} + {e}^{j \frac{π}{4}} {h}_{1} + {e}^{j \frac{π}{4}} {h}_{2} ;$$

and state “0000” transitions to state “1111”.
   In an embodiment, the branch metrics for m branches are computed as BMₘ[k]=|y[k]−xₘ[k]|². In another embodiment, the branch metrics for m branches are computed as BMₘ[k]=|y[k]−xₘ[k]|. Note that the constraint length, TL, and modulation scheme are exemplary only and other modified Viterbi equalizers have a different constraint length, TL, or modulation scheme.

Thus, techniques for reducing the effects of ISI and for reducing phase offset and frequency offset in a demodulator are described. Embodiments of a demodulator include a Kalman filter-based PLL that provides a frequency or phase offset compensated signal to the modified Viterbi equalizer and the Kalman filter-based PLL receives a reference signal that is a reconstructed version of an ISI-corrupted symbol for use in computing the phase error. In an embodiment, that reference signal is based on an instant decision or an expected ISI-corrupted symbol of the modified Viterbi equalizer that does not require waiting for a traceback length to generate the reference symbol for the Kalman filter.

The description of the invention set forth herein is illustrative and is not intended to limit the scope of the invention as set forth in the following claims. For example, while the invention has been described in an embodiment in which an Access Address field of a BLE packet is used, any predetermined symbols of a communications packet (e.g., training symbols) may be used. The terms “first,” “second,” “third,” and so forth, as used in the claims, unless otherwise clear by context, are to distinguish between different items in the claims and do not otherwise indicate or imply any order in time, location, or quality. For example, “a first received signal” and “a second received signal” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. A method for receiving a radio frequency signal comprising:
correcting a frequency or phase offset in a baseband version of a received radio frequency signal to generate a corrected signal based on the baseband version of the received radio frequency signal and a feedback signal;
equalizing the corrected signal using maximum likelihood signal estimation and a channel estimate to generate an equalized signal; and
providing the feedback signal, the feedback signal being based on the corrected signal and the channel estimate.

2. The method as recited in claim 1
wherein providing the feedback signal includes a modified Viterbi equalizer providing an expected corrupted symbol at time index k as the feedback signal at the time index k,
wherein equalizing the corrected signal includes providing a plurality of equalized symbols of the equalized signal by the modified Viterbi equalizer, the modified Viterbi equalizer having a traceback length (TL), where TL is an integer greater than one and the plurality of equalized symbols are provided at time index k+TL, and
wherein the modified Viterbi equalizer has a plurality of states, the plurality of states being associated with corresponding accumulated path metrics, and the expected corrupted symbol corresponds to a most likely state selected from the plurality of states based on the corresponding accumulated path metrics at the time index k.

3. The method as recited in claim 1
wherein providing the feedback signal includes convolving an instant decision symbol of a modified Viterbi equalizer at time index k with the channel estimate,
wherein equalizing the corrected signal includes providing a plurality of equalized symbols of the equalized signal by the modified Viterbi equalizer, the modified Viterbi equalizer having a traceback length (TL), where TL is an integer greater than one and the plurality of equalized symbols are provided at time index k+TL, and
wherein the modified Viterbi equalizer has a plurality of states, the plurality of states being associated with corresponding accumulated path metrics, and the instant decision symbol corresponds to a most likely state selected from the plurality of states based on the corresponding accumulated path metrics at the time index k.

4. The method as recited in claim 1
wherein providing the feedback signal comprises:
slicing the corrected signal at time index k to generate a sliced corrected symbol; and
convolving the sliced corrected symbol with the channel estimate to generate a symbol of the feedback signal at time index k, and
wherein equalizing the corrected signal includes providing a plurality of equalized symbols by a Viterbi equalizer having a traceback length (TL), where TL is an integer greater than one and the plurality of equalized symbols are provided at time index k+TL.

5. The method as recited in claim 1 wherein correcting the frequency or phase offset comprises:
computing an error signal based on the baseband version of the received radio frequency signal and a reference signal;
generating an error correction signal based on a phase of the error signal and a predicted instantaneous phase signal; and
providing the corrected signal based on the baseband version of the received radio frequency signal and the error correction signal.

6. The method as recited in claim 5
wherein in a training mode of operation, the reference signal is generated based on predetermined samples, and
wherein in a tracking mode of operation, the reference signal is based on the feedback signal.

7. The method as recited in claim 5 wherein generating the error correction signal comprises:
generating a phase difference signal based on the phase of the error signal and a prior value of the predicted instantaneous phase signal; and
combining a proportional version of the phase difference signal with an integrated version of the phase difference signal to generate a predicted frequency signal.

8. The method as recited in claim 7 wherein generating the error correction signal further comprises:
integrating the predicted frequency signal to generate the predicted instantaneous phase signal.

9. A wireless communications receiver comprising:
an error correction circuit configured to compensate for a frequency or phase offset in a baseband version of a received radio frequency signal and to generate a corrected signal based on the baseband version of the received radio frequency signal and a feedback signal; and
a Viterbi equalizer configured to generate an equalized received signal based on the corrected signal and a channel estimate,
wherein the feedback signal is generated based on the corrected signal and the channel estimate.

10. The wireless communications receiver as recited in claim 9
wherein the Viterbi equalizer is configured to provide an expected corrupted symbol at time index k as the feedback signal at the time index k, and is configured to provide a plurality of equalized symbols of the equalized received signal,
wherein the Viterbi equalizer has a traceback length (TL), where TL is an integer greater than one and the plurality of equalized symbols are provided at time index k+TL
wherein the Viterbi equalizer has a plurality of states, the plurality of states being associated with corresponding accumulated path metrics, and the expected corrupted symbol corresponds to a most likely state selected from the plurality of states based on the corresponding accumulated path metrics at the time index k.

11. The wireless communications receiver as recited in claim 9 further comprising:
a circuit configured to convolve an instant decision symbol of the Viterbi equalizer at time index k with the channel estimate,
wherein the Viterbi equalizer has a traceback length (TL), where TL is an integer greater than one and is configured to provide a plurality of equalized symbols of the equalized received signal at time index k+TL, and
wherein the Viterbi equalizer has a plurality of states, the plurality of states being associated with corresponding accumulated path metrics, and the instant decision symbol corresponds to a most likely state selected from the plurality of states based on the corresponding accumulated path metrics at the time index k.

12. The wireless communications receiver as recited in claim 9 further comprising:
a slicer circuit configured to slice the corrected signal at time index k to generate a sliced corrected symbol; and
a feedback circuit configured to generate the feedback signal at the time index k based on a convolution of the sliced corrected symbol with the channel estimate,
wherein the Viterbi equalizer has a traceback length (TL), where TL is an integer greater than one, and is configured to provide a plurality of equalized symbols at time index k+TL.

13. The wireless communications receiver as recited in claim 9 further comprising:
a phase-locked loop configured to generate an error correction signal based on the baseband version of the received radio frequency signal and a reference signal.

14. The wireless communications receiver as recited in claim 13 wherein the phase-locked loop comprises:
a phase detector configured to generate an error signal based on the baseband version of the received radio frequency signal and the reference signal; and
a Kalman filter configured to generate the error correction signal based on a phase of the error signal and a predicted instantaneous phase of the error signal.

15. The wireless communications receiver as recited in claim 14 further comprising a select circuit,
wherein in a training mode of operation, the select circuit provides predetermined samples as the reference signal, and
wherein in a tracking mode of operation, the select circuit provides a signal based on the feedback signal as the reference signal.

16. The wireless communications receiver as recited in claim 14 wherein the phase-locked loop comprises:
a phase difference circuit configured to generate a phase error signal based on a phase of the error signal and the predicted instantaneous phase of the error signal; and
a proportional integral time-invariant controller responsive to the phase error signal,
wherein the predicted instantaneous phase of the error signal is based on an output of the proportional integral time-invariant controller.

17. The wireless communications receiver as recited in claim 16 wherein the phase-locked loop further comprises:
an integrator configured to generate the predicted instantaneous phase of the error signal based on the output of the proportional integral time-invariant controller.

18. An apparatus comprising:
means for reducing frequency or phase offset in a baseband version of a received radio frequency signal to generate a corrected signal based on the baseband version of the received radio frequency signal and a feedback signal; and
means for removing inter-symbol interference from the corrected signal using maximum likelihood signal estimation equalization based on a channel estimate and the corrected signal to generate an equalized received signal.

19. The apparatus as recited in claim 18
wherein the means for removing inter-symbol interference provides an expected corrupted symbol at time index k as the feedback signal at the time index k, and provides a plurality of equalized symbols of the equalized received signal at time index k+TL, where TL is an integer greater than one, and
wherein the means for removing inter-symbol interference has a plurality of states, the plurality of states being associated with corresponding accumulated path metrics, and the expected corrupted symbol corresponds to a most likely state selected from the plurality of states based on the corresponding accumulated path metrics at the time index k.

20. The apparatus as recited in claim 18 further comprising:
means for convolving an instant decision symbol at time index k with the channel estimate to generate the feedback signal at the time index k,
wherein the means for removing inter-symbol interference provides a plurality of equalized symbols of the equalized received signal at time index k+TL, where TL is an integer greater than one, and
wherein the means for removing inter-symbol interference has a plurality of states, the plurality of states being associated with corresponding accumulated path metrics, and the instant decision symbol corresponds to a most likely state selected from the plurality of states based on the corresponding accumulated path metrics at the time index k.
